(19) United States
(12) Patent Application Publication
(10) Pub. No.: US 2018/0208321 A1
(43) Pub. Date: Jul. 26, 2018

(54) PHOTOVOLTAIC-BASED INTEGRATED POWER SYSTEMS FOR AIRBORNE VEHICLES

(71) Applicant: Ascent Solar Technologies, Inc., Thornton, CO (US)

(72) Inventors: Joseph H. Armstrong, Littleton, CO (US); Stephanie Persha Retureta, Highlands Ranch, CO (US); lnbo Lee, Albuquerque, NM (US)

(73) Assignee: Ascent Solar Technologies, Inc., Thornton, CO (US)

(21) Appl. No.: 15/862,143

(22) Filed: Jan. 4, 2018

Related U.S. Application Data
(60) Provisional application No. 62/442,437, filed on Jan. 5, 2017.

(51) Int. Cl. B64D 27/02; B64C 39/02; H01L 31/048; H01M 2/10

(52) U.S. Cl. CPC B64D 27/02; B64C 39/024; B64C 2201/06; H01M 2/1083; B64C 2201/042; H01L 31/048

(57) ABSTRACT

A photovoltaic-based integrated power system for aerial vehicles includes (1) an integrated power management, regulation, and distribution (PMRD) subsystem including a case having an opening, (2) a case for the PMRD system, and (3) a flexible lightweight photovoltaic module capable of being applied conformally onto one or more aerodynamic surfaces.

### CROSS-REFERENCE TO RELATED APPLICATIONS

This application claims benefit of priority to U.S. Provisional Application Ser. No. 62/442,437 filed Jan. 5, 2017 which is incorporated herein by reference.

### BACKGROUND

With advances in lightweight material, brushless motor and lithium-ion battery technologies, it is now possible for long-duration electric-only powered flights on aircraft. Small scale unmanned aerial vehicles (sUAVs) have an optimum payload to aerodynamic lift that can fully take advantage of electric power for propulsion, communications, and controls. Vehicles of this type include payload that also require electric power for powering cameras, sensors, and data streaming. Vehicles of this type must balance airspeed, where faster flight often consumes more power but also provides greater lift. Greater lift can allow for larger batteries but generally at the cost of available payload. Generally speaking, longer flight duration of sUAV can be of greater benefit as their primary mission often depends upon loitering over a given area.

sUAVs can typically be broken down into two categories, namely multirotor and fixed wing aircraft. Multirotors are commonly seen in both the hobby and professional grades and often are used for surveillance where takeoff and landing areas are limited, and the payload can include high-definition video and high-resolution still cameras. In many cases, additional controls can be realized with an autopilot coupled with global positioning satellites (GPS). However, as all aerodynamic lift is accounted for by electricity, the flight time for multirotor sUAV can be lower than fixed wing sUAV. The reason is that fixed wing sUAV relies on lift generated by the speed of the wings through the air, as well as from thermal lift from ground sources. As a result, fixed-wing sUAV can turn off propulsion periodically and still remain airborne.

Power systems for sUAV need to energize propulsion systems, as well as radio communications, control surfaces, sensors, cameras, and digital data streaming. Furthermore, sUAV may also include autopilot and datalogging systems that control flight autonomously and record all data generated onboard. While sUAV vehicles can glide if they lose propulsion, they cannot fly in control unless power is maintained to the radio communications/autopilot and the control surfaces.

Photovoltaic (PV) power systems have been widely used for generating electrical power from sunlight. Most often, these systems have consisted of heavy, rigid glass PV panels that generate direct current (DC), and a balance of systems (BOS) that may consist of a combination of power management circuitry, and battery storage with charge control circuitry. Because PV power systems generate more energy the longer they are exposed to the sun, they match up well with the primary requirement of sUAV, that is, longer operational time is strongly desired.

Lightweight and flexible PV modules, frequently referred to as PV blankets, have been developed as an alternative to rigid glass PV panels. PV blankets are commercially available and are sufficiently light to allow for airborne power generation. However, if the PV blanket is not required to withstand extreme weather, such as driving rain or hail, and is not required to survive physical damage, the construction of a flexible PV blanket can be significantly simplified, thereby dramatically reducing the mass of the blanket as well.

While mating lightweight PV and sUAV appears to be logical, the way PV generates power is not necessarily conducive to the power needs of a sUAV, however. Power output of a photovoltaic device, such as a single PV cell or a PV module including a plurality of PV cells, is described as DC, but the values are dynamic, and voltage and current depend heavily on the electrical load imparted upon the photovoltaic device. At zero load, or open circuit, the PV device generates no current and presents its highest voltage, commonly referred to as open-circuit voltage (Vₒₙ). As the electrical load attached to the PV device increases, its voltage will remain relatively stable until reaching a point where the voltage will continue to decrease with increasing load (i.e., increasing electrical current). When the photovoltaic device is electrically shorted, the voltage across the device is zero, and the current is referred to as the short-circuit current (or I_{sc}).

Electrical power (P) is calculated by the product of the voltage and current. Where the voltage is relatively stable as current (load) increases, the amount of electrical power generated also increases. As the voltage begins to drop with increasing current (load), the power generated decreases. At the point where peak power output is achieved, commonly referred to as the maximum power point, the voltage and current is commonly referred to as Vₘₐₓ and Iₘₐₓ, respectively.

For example, FIG. 1 illustrates a dynamic response 100 of an exemplary PV device, such as a PV cell or a module of a plurality of PV cells, at 100% light intensity and at 70% light intensity. As illustrated, the PV device will generate a V_{oc} 102 at no load and 100% light intensity. If the PV device is electrically shorted (e.g. both leads are connected together), there is no voltage across the device, and I_{sc} 104 flows through the photovoltaic device at 100% light intensity. The PV device has a maximum power point 106 at 100% light intensity.

However, performance of the PV device is significantly different if less light impinges upon the front surface. For example, both V_{OC} and I_{sc} shift noticeably lower to V_{oc} 108 and I_{sc} 110, respectively, at 70% light intensity. Consequentially, the maximum power point 112 at 70% light intensity is lower and occurs at a lower output voltage than maximum power point 106 at 100% light intensity. Thus, if electronics attached to the PV device are designed to run at a fixed voltage corresponding to maximum power point 106, the PV device will not operate at its maximum power point at 70% light intensity, because the operating voltage will not correspond to the maximum power point at 70% light intensity.

Additionally, environmental conditions affect the maximum power available, as well as the voltage and current at these peak conditions. These environmental conditions include the angle of sunlight impinging the PV device, the ambient temperature at the device's location, the increasing temperature of the PV device as the sunlight impinges upon it, the interference of sunlight reaching the PV device due to smoke, fog, dust and dirt, precipitation, leaves, grass, and other naturally occurring phenomenon. Given that the very nature of airborne power systems dictates that they may not be ideally inclined towards the sun, operating under ideal temperature conditions, or be free of environmental contaminants blocking sunlight, the PV devices likely will not operate at their maximum performance levels as measured under standard test conditions.

Accordingly, conventional portable power systems will typically not operate at their maximum possible level for a number of reasons. Additionally, as the voltage and current at maximum power point may vary under various conditions, PV blankets must be installed and operated by someone who understands how they operate, otherwise they will likely not obtain high performance. For someone who wants to operate a airborne PV system, but is not an expert in PV systems, clearly this is a disadvantage.

Any circuitry that is intended to connect to a PV device will ideally cause the PV device to operate at a voltage and current corresponding to the PV device's maximum power point. However, as stated above, the maximum power point can change for a variety of reasons, and as such, a means for adjusting the load that the photovoltaic device experiences must be constantly adjusted to maximize its performance. Furthermore, there is no guarantee that this voltage/current corresponding to maximum power point has any relation to what the attached load may require.

Power systems for sUAV can vary dramatically, but for simplicity's sake, we shall consider those systems derived from high-end hobby-grade aircraft. In FIG. 2, a battery system 202, typically based on lithium-ion technology for high performance, is connected to an electronic speed control 204 (ESC). With today's brushless motor technology, the ESC has three leads that connect directly to the motor that provides propulsion.

In order to provide power to other electrical systems, such as servos that activate control surfaces, the ESC often contains what is known as a battery elimination circuit (ESC). While this circuitry provides the power for the servos, it normally does not provide power for other electronic devices that operate at different voltages. Because of the high-frequency AC signal generated by the ESC to operate the brushless AC motor technology, it is likely that the power connection may also contain ripple and other noise that may be problematic with any electronics attached to that power. As a result, it is often desired to have a separate battery source for sensitive electronics, although the addition of another power generation system also increases system weight.

The key features for a system that mates the advantages of a lightweight PV system to the power requirements of a sUAV would then include: i) lightweight, flexible PV systems that can conform to fixed wing surfaces, as well as any other surface exposed to sunlight, ii) a power management, regulation, and distribution (PMRD) system that includes a) maximum peak power tracking to generate the maximum power available under widely varying angle to the sun, temperature, and light intensity, b) charge control circuitry matched to the chemistry and configuration of the battery, c) balance charge control to ensure safe, reliable charging of multiple cell battery construction that is typical of sUAV system, d) utilizes existing battery technologies to make adaptation of the PV system easier, and e) provide a minimum of one regulated, and electrically filtered, power bus to provide clean electrical power to servos, radios, sensors, cameras, autopilots, GPS and other sensors.

### SUMMARY

Applicant has developed photovoltaic-based integrated power systems for airborne vehicles that may at least partially overcome one or more the problems discussed above. These renewable airborne power systems (RAPS) advantageously include both aircraft mounted photovoltaic devices and a BOS with several components co-packaged in a single assembly, thereby potentially eliminating the need for multiple discrete components and associated interconnecting cables. Additionally, the BOS include maximum power point tracking (MPPT) circuitry, which as discussed below, is capable of causing the photovoltaic devices to operate substantially at their maximum point without user intervention, thereby potentially allowing the airborne power systems to achieve high performance.

RAPS begins with a lightweight, flexible PV module that is sufficiently flexible to conform to an aerodynamic wing or fuselage surface. RAPS also includes a power management, regulation, and distribution (PMRD) that provides an interface to a traditional sUAV energy storage (battery). In certain embodiments, the battery subsystem includes lithium-ion (Li-Ion) and/or lithium-polymer (LiPo) batteries to promote lightweight, robust, powerful, and stable energy storage. RAPS also includes charge controlling circuitry that is matched to the construction and chemistry of the battery, and in order to safely charge a multi-cell battery construction that is typical of sUAV, a balance charging circuit ensures that all cells in series are charged without possible runaway conditions.

PMRD further include power conversion circuitry for providing one or more regulated power outputs for electrically connected components that can include controls, autopilot, GPS, sensors, cameras and other electronics. Some embodiments include a 5 VDC regulated, filtered output voltage rail typically used for powering servos and other electronics. This embodiment may also include this output in a traditional USB 2.x configuration. Additional embodiments may also include a 12VDC regulated, filtered output for some video cameras and other electronics. Furthermore, the regulated power output in other embodiments may include an intelligent ‘adaptable’ power source, such as USB 3.1 Power Delivery (PD) where the power source negotiates with the component requesting power to deliver up to 20VDC and up to 5 A current as required by that component. A further advantage of this embodiment is that the USB 3.1 PD protocol enables power transfer and regulation in either direction, thereby enabling this portion of the circuit to compliment the PV charging as needed.

One common aspect to the proposed PV interface is that it must be lightweight. A combination of circuit design and case construction must keep weight in mind, thus, any potting to protect electronics must be lightweight as well, and case design must utilize non-traditional materials and construction that is more typical of the sUAV as opposed to traditional electronic components. Optionally, RAPS case construction can include mounting surfaces for other components.

### BRIEF DESCRIPTION OF THE DRAWINGS

FIG. 1 illustrates the relationship between voltage and current of an exemplary photovoltaic device, along with the corresponding power output as a function of electrical load (current).

FIG. 2 is a block diagram of a traditional sUAV power system, both the airborne portion and the ground-based charging system, according to an embodiment.

FIG. 3 is a block diagram of a photovoltaic-based integrated airborne power system for airborne vehicles, according to an embodiment.

FIG. 4 is a top plan view of a photovoltaic-based integrated power system for airborne vehicles, according to an embodiment.

FIGS. 5-9 are each different perspective views of a photovoltaic-based integrated power system for airborne vehicles, according to an embodiment.

### DETAILED DESCRIPTION

It is noted that, for purposes of illustrative clarity, certain elements in the drawings may not be drawn to scale. Specific instances of an item may be referred to by use of a numeral in parentheses (e.g., FILTERED POWER BUS 320(1)) while numerals without parentheses refer to any such item (e.g., FILTERED POWER BUS). In the present disclosure, “cm” refers to centimeters, “m” refers to meters, “A” refers to amperes, “mA” refers to milliamperes, and “V” refers to volts.

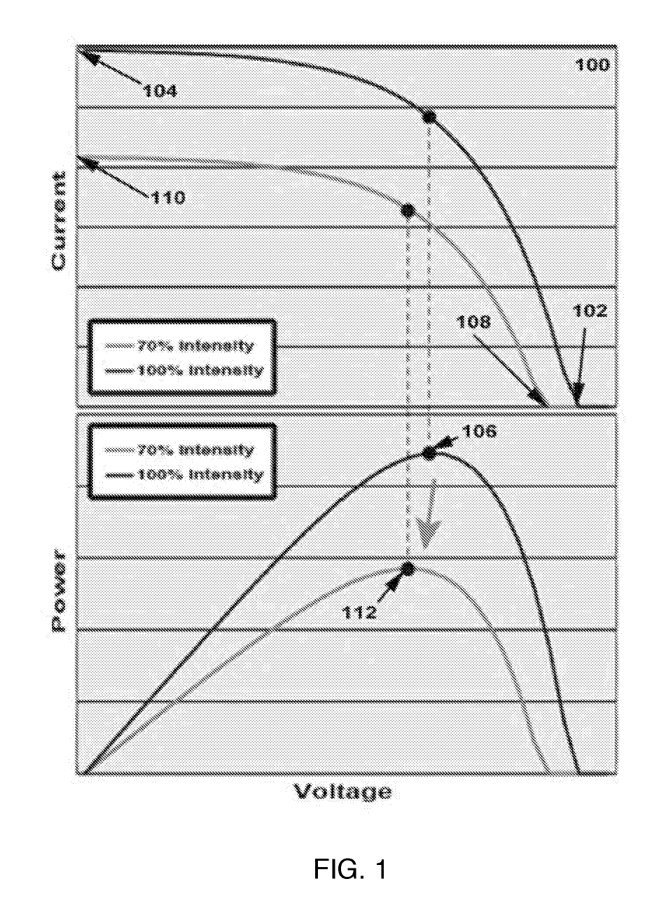

As discussed above, the PV-based integrated power systems for aerial vehicles developed by Applicant include MPPT circuitry. The MPPT circuitry is designed to adjust the voltage/current position along the power curve to determine the position of the maximum power point. This can be achieved by scanning the load that the PV device ‘sees’, and as the scan proceeds, the MPPT circuitry identifies the position of the maximum power point and maintains PV device operation at this voltage point and current point. Thus, the MPPT circuitry does not need to know the conditions that the PV device is actually experiencing; rather, the MPPT circuitry will adjust its input impedance, thereby adjusting the load condition that the PV device is ‘seeing’, to identify and lock into the maximum power point. For example, if a PV device has characteristics like that illustrated in FIG. 1, the MPPT circuitry will adjust its input impedance such that the PV device operates at maximum power point 106
or 112 at 100% and 70% light intensity, respectively. By effectively decoupling the actual load that the PV device ‘sees’ from the PV device operation, the MPPT can continuously adjust the effective PV load to ensure the PV device can operate at maximum efficiency. This is particularly important with respect to sUAV whose normal motions in the air ensure that the vehicle will seldom be at optimum solar angles and intensities.

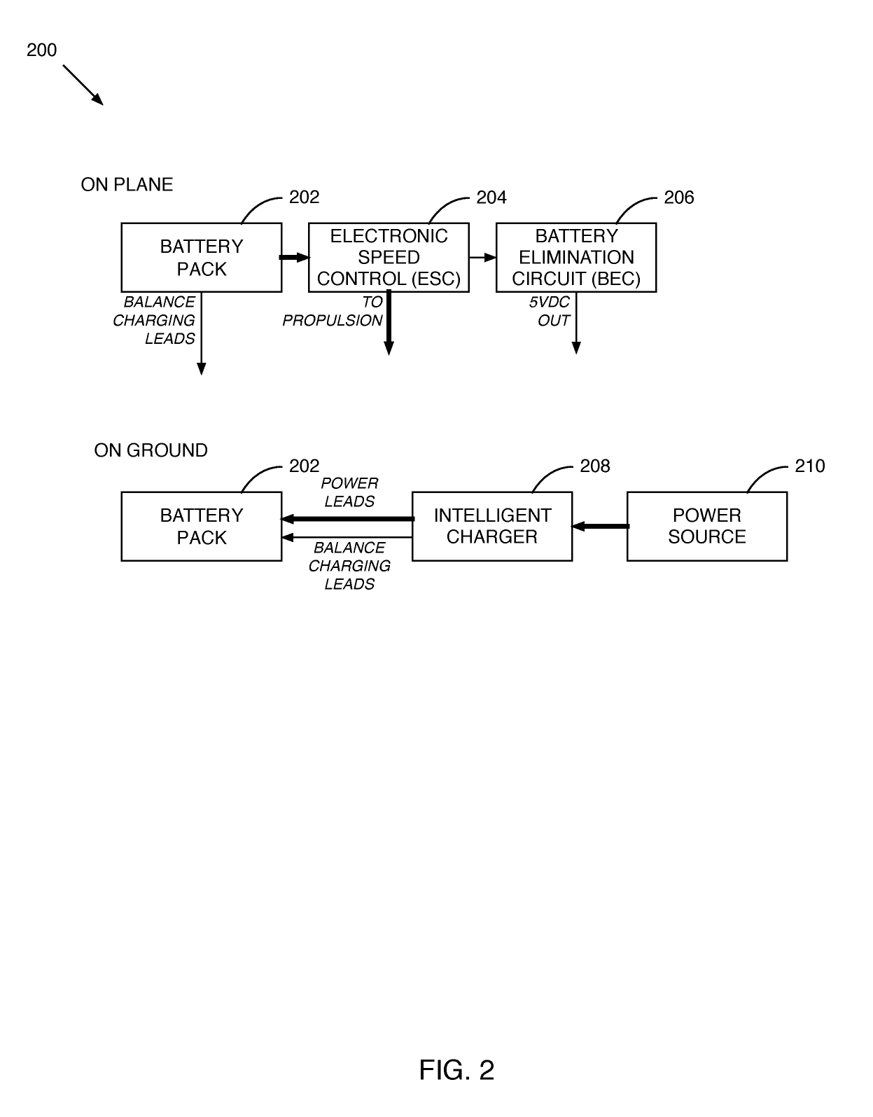

While sUAV power systems vary greatly in design, one embodiment of an sUAV power system 200 shown in FIG. 2 utilizes a construct that includes a high performance battery pack 202 that is connected via a high current power line to an electronic speed control 204 (ESC). The ESC 204 regulates the speed of the attached electric propulsion system. In one embodiment, the ESC 204 is designed to regulate the AC power to a brushless electric motor. In other embodiments, the ESC 204 regulates the DC power available to a brush electric motor. As some sUAV rely upon a 5VDC circuit to power radio controls to electrical actuators, or servos, to operate control surfaces, one embodiment includes a battery elimination circuit 206 (BEC).

Because batteries must be recharged between flights, the power system 200 must also include a means for charging the system on the ground. In one embodiment, the battery pack 202 is removed from the sUAV in order to charge in a ground station. An intelligent charger 208 is used to safely charge a the multi-cell battery by balance charging, or the regulation of the charging function to ensure that each series circuit in the battery pack 202 is charged safely and to prevent any of these series circuits to charge significantly different than other strings. The intelligent charger 208 operates from a wide range of power sources 210. In some embodiments, power source 210 may include a portable DC power source, a generator (either AC or DC based), or power grid.

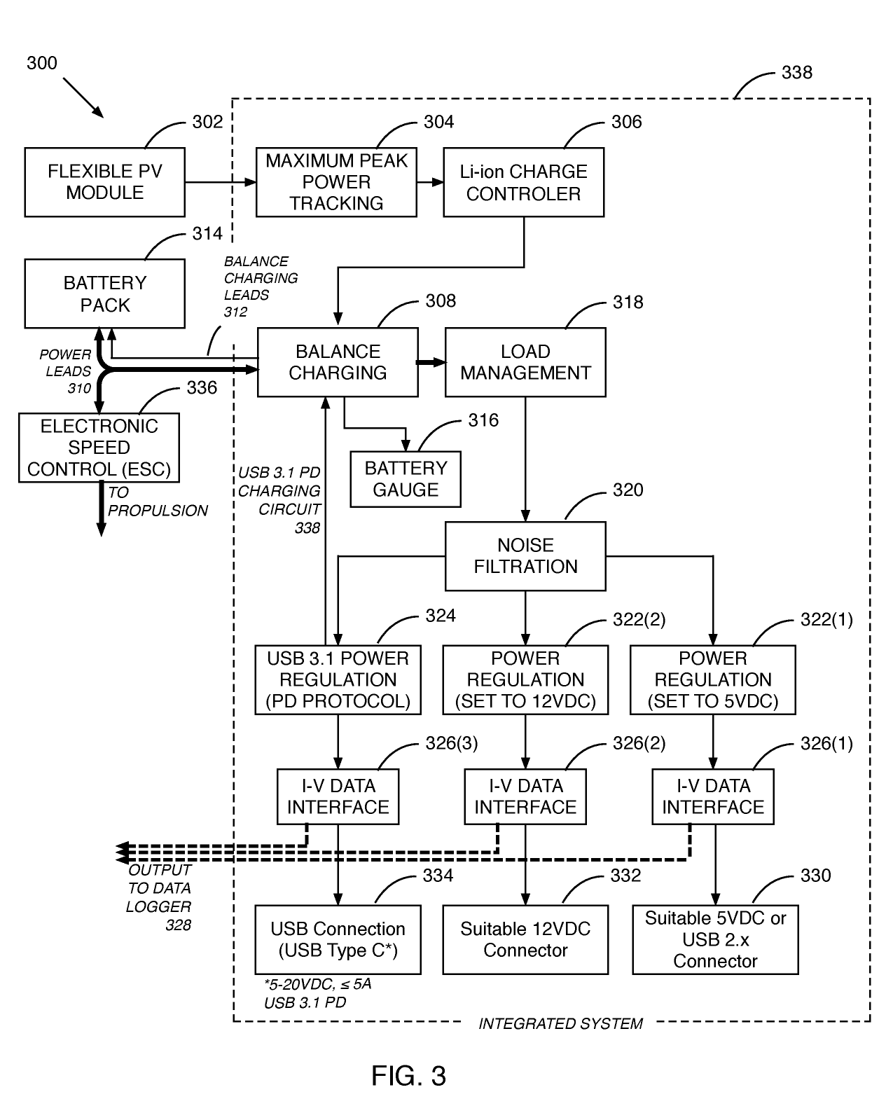

RAPS is designed to interface with an existing sUAV power system, or a clean-sheet design as well. The best location for existing systems illustrated in 200 is between the battery pack 202 and the ESC 204. In this location, existing interface points can interface with key systems. FIG. 3 shows one embodiment of the RAPS that connects to the existing electrical system 200. RAPS includes one or more photovoltaic modules 302 that is then interfaced with a maximum peak power tracking (MPPT) system 304. Flexible PV module 302 includes a plurality of PV cells for converting light, such as sunlight, into electricity. The PV cells are electrically coupled in series and/or in parallel, to obtain a desired output voltage and output current capability. In some embodiments, flexible PV module 302 includes a plurality of electrically interconnected flexible PV submodules monolithically integrated onto a common flexible substrate. Each PV submodule, in turn, includes a plurality of electrically interconnected flexible thin-film PV cells monolithically integrated onto the flexible substrate. The PV cells of flexible PV module 302 include, for example, copper-indium-gallium-selenide (CIGS) PV cells, copper-indium-gallium-sulfur-selenide (CIGSSe) PV cells, copper zinc tin sulfide (CZTS) PV cells, cadmium-telluride (CdTe) PV cells, silicon (Si) PV cells, and/or amorphous silicon (a-Si) PV cells. In some other embodiments, the PV cells of flexible PV module 302 include flexible crystalline PV cells, such as a thin crystalline silicon (Si) photovoltaic cells or thin gallium arsenide (GaAs) photovoltaic cells. The flexible crystalline PV cells are for example fabricated by epitaxial lift-off (ELO) or by mechanical thinning of crystalline wafers, in these embodiments.

The MPPT system 304 provides reliable DC power to a charge controller 306 that is matched to the chemistry and construction of the battery system 314, that is, voltage profiles are set for a given battery chemistry and the number of cells in series in the battery pack 312. In some embodiments, battery subsystem 314 includes one or more lithium ion (LiIon) batteries, lithium polymer (LiPo) batteries, or zinc-air batteries.

Output from the charge controller 306 provides power to a balance charging circuit 308. The balance charging circuit 308 is matched to the battery cell construction so that each cell string is managed to keep them within one another so that the charge controller 306 does not inadvertently overcharge any individual string. To facilitate this, the balance charging circuit 308 is connected to the battery subsystem 314 via the high power leads 310 and the lower current balance charging leads 312. If the given battery subsystem 314 already contains a balance charging circuit, or if the battery chemistry does not require individual cell charge balancing as is the case with lithium batteries, this circuit may be eliminated. In this embodiment, the battery is connected to a battery capacity gauge 316 to allow the user to establish the charge state of the battery subsystem 314 without removing it from the vehicle.

The functions of MPPT system 304, charge controller 306, and load management circuitry 318 may be combined into a single circuit board in some embodiments. Other embodiments may include all of the components above, with the addition of the balance charging circuit 308, can be also integrated into the same single circuit board.

The load management circuitry 318 ensures that the available power from PV or the battery subsystem 314 is provided to the regulated outputs as a single unit. As many of the components in small UAVs involve electrical components that can contribute significantly to electrical noise, such as the propulsion motor, control surface servos, etc., an electronic noise filtration system 320 is desirable. This system can be centrally located as shown in FIG. 3, or as individual units filtering power to each of the power management systems separately (322, 324). These filtration systems 320 serve several purposes. First, many of the regulation circuits can be susceptible to electrical noise in the power in signal, so filtration will allow these units to operate more reliably. Second, regulated power circuits provide power to sensitive electronic equipment, including video transmitters, autopilots, or sensors. RAPS utilizes at least one power regulation circuit that is set to a desired voltage for the sUAV community. These regulation circuits can be fixed (322) or automatically adjustable (324), depending upon the user's needs. In one embodiment shown in FIG. 3, three regulated circuits are utilized, one for 5VDC 322(1), another 12VDC 322(2), and a third regulator 324 that can sense the voltage requirement of the component connected to it and automatically adjust the output to best match its needs. Such automatically sensing regulation circuits may include USB 3.1 that follow the Power Delivery (PD) protocol. Circuits of this type are now being employed in a wide range of electronic products that enable a truly universal charging platform. Also illustrated in FIG. 3 is the fact that USB 3.1 PD can function both as a power delivery system as well as a power accommodation function where the same interface can both charge a battery as well as take power from it as needed. Thus, this single interface can power a wide range of electronics that require between 5VDC and 20VDC and a maximum of 5 A, and it can also use this same interface as an external power charging port that can combine both solar and USB 3.1 PD to charge the vehicle's battery subsystem 314.

As the health of the vehicle is of great importance, RAPS also includes a low-power I-V (current-voltage) data interface 326 to convert the voltage and current of the filtered power circuit to either analog or digital data 328 for the data logging and/or autopilot circuits that reports the voltage and current output of each of the regulated circuits 322 and 324. In the interest of rapid integration of RAPS into the vehicle, suitable DC connectors 330 and 332 can be used for the static DC power output, and a USB 3.1 compatible connector that complies to PD can be used, such as a USB Type C.

In order to transfer the power generated by the PV and stored in the battery subsystem 314 to the vehicle, the battery subsystem 314 is connected to the electronic speed control (ESC) 336 as was noted earlier in FIG. 2.

In one embodiment, the MPPT 304, charge controller 306, balance charging circuitry 308, battery capacity gauge 316, load management 318, noise filtration 320, regulated power circuits 322 and 324, I-V circuit boards 326 and connectors 330, 332, and 334, are integrated into a compact, lightweight case 338 to define the power management, regulation, and distribution (PMRD). Electrical connections exiting the case include input from the flexible PV module 302, I-V signal interfaces 326, battery power 310, and balance circuitry leads 312. Case 338 is optionally potted to protect the PMRD circuitry and wiring therein from damage from moisture, dirt, and vibration. In some embodiments, case 302 also provides a rugged mounting point for various accessories.

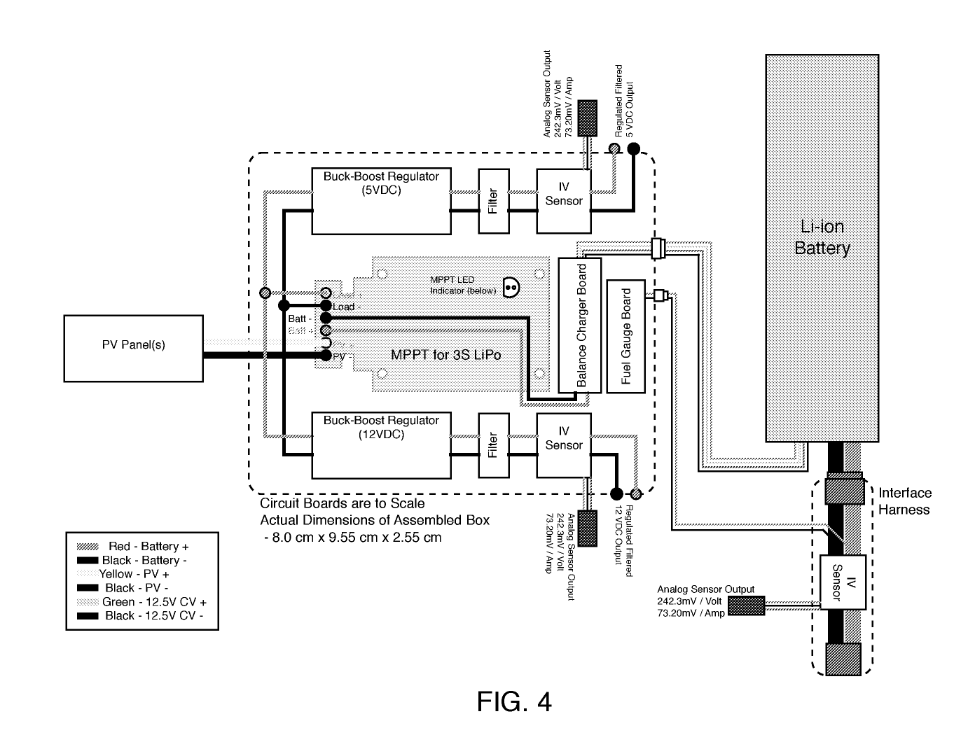

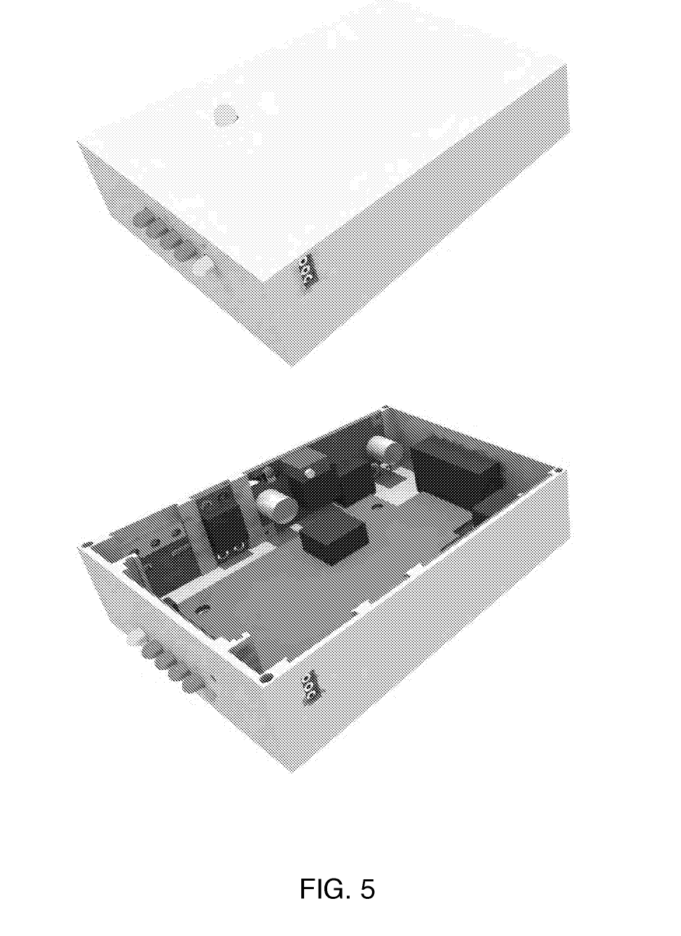

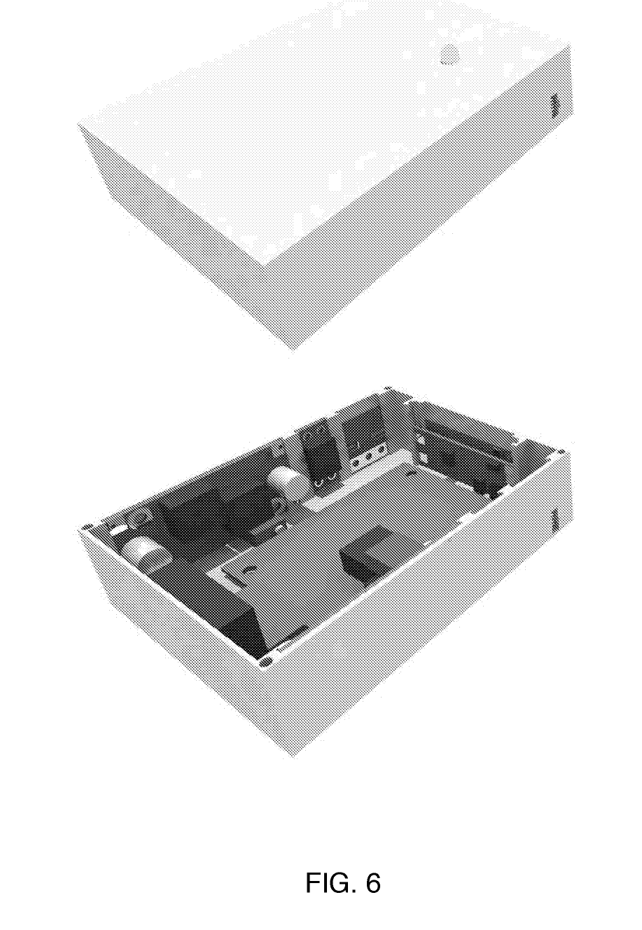

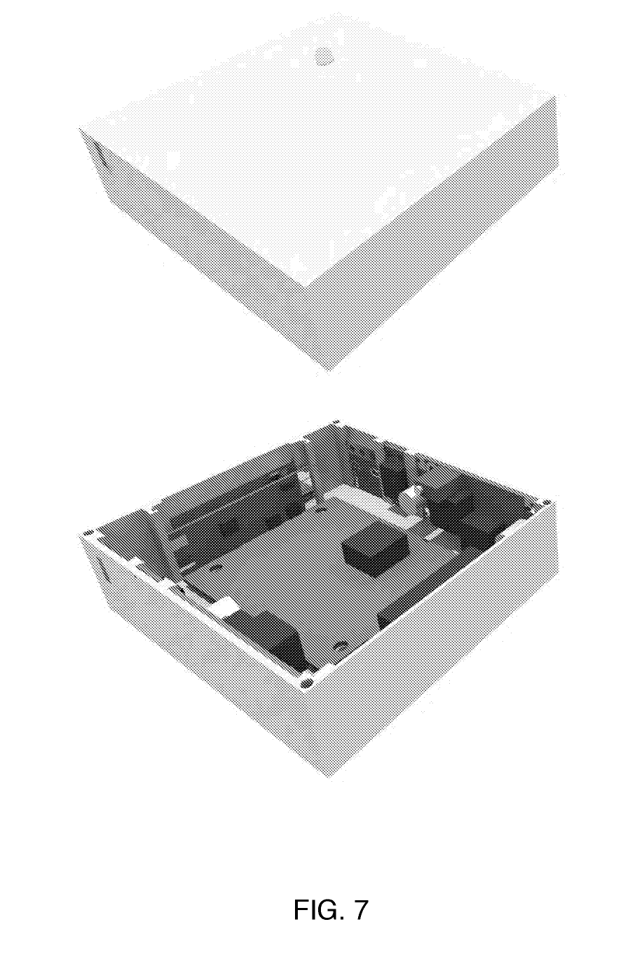

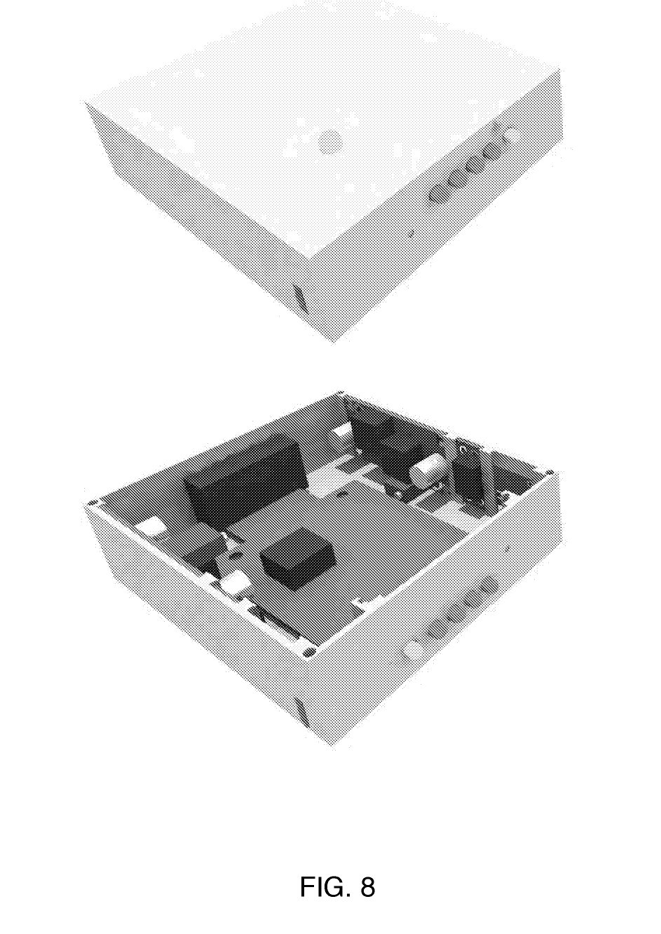

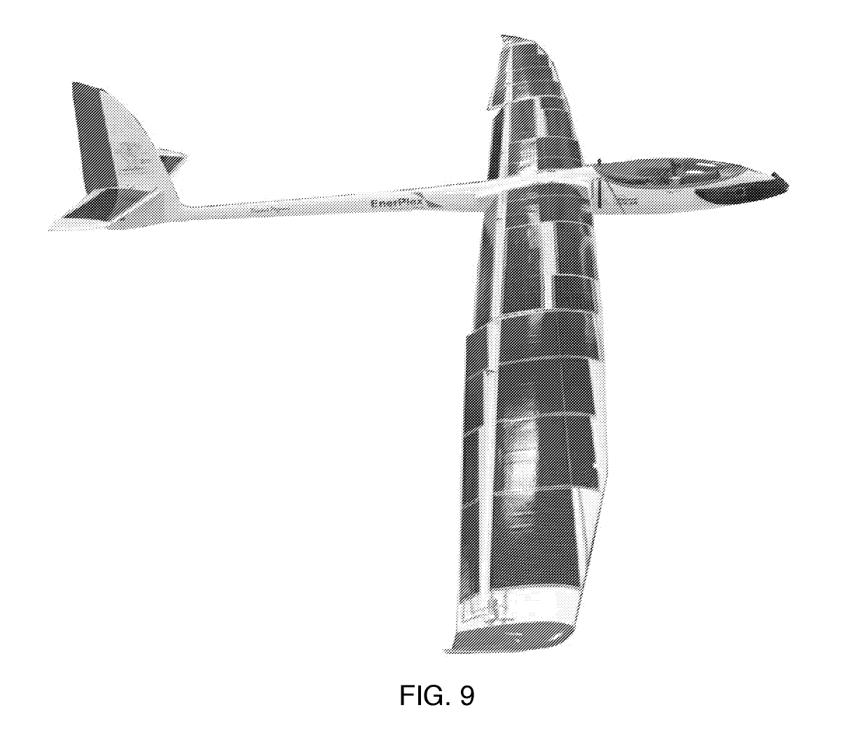

FIG. 4 is a top plan view of one configuration of the PMRD electrical interface contained in case 338, illustrating the approximate relationship between components within the case. FIGS. 5-8 each show a different perspective view of a power management, regulation, and distribution (PMRD) subsystem for the photovoltaic-based renewable power management, regulation, and distribution system 324. Finally FIG. 9 is a photograph of the PV blankets 302 attached to the surface of a sUAV utilizing components in the PMRD to integrate PV power.

Changes may be made in the above apparatus, systems and methods without departing from the scope hereof, and therefore, it is intended that all matter contained in the above description or shown in the accompanying drawings be interpreted as illustrative and not in a limiting sense. It is also to be understood that the following claims are to cover certain generic and specific features described herein.

What is claimed is:

1. A photovoltaic-based renewable aerial power system (RAPS) for small unmanned aerial vehicles (sUAVs) comprising:
at least one flexible photovoltaic module capable of being disposed onto an aerodynamic surface, such as a wing or fuselage;
an integrated power management, regulation, and distribution (PMRD) subsystem that interfaces with the sUAV power system, including a case having an opening; and
at least one regulated and filtered power source within the PMRD necessary for sUAV operation.

2. The system of claim 1, the flexible photovoltaic module comprising at least one flexible thin-film photovoltaic device selected from the group consisting of a copper-indium-gallium-selenide (CIGS) photovoltaic device, a copper-indium-gallium-sulfur-selenide (CIGSSe) photovoltaic device, a copper zinc tin sulfide (CZTS) photovoltaic device, a cadmium-telluride (CdTe) photovoltaic device, a silicon (Si) photovoltaic device, and an amorphous silicon (a-Si) photovoltaic device.

3. The system of claim 1, the flexible photovoltaic module comprising at least one flexible crystalline photovoltaic device selected from the group consisting of a thin crystalline silicon (Si) photovoltaic device and a thin gallium arsenide (GaAs) photovoltaic device.

4. The system of claim 3, the at least one flexible crystalline photovoltaic device being fabricated by epitaxial lift-off (ELO) or by mechanical thinning of crystalline wafers.

5. The system of claim 1, the flexible photovoltaic module including electrical terminals and attached leads that enable passage through the surface of the airframe to reach the power management circuitry.

6. The system of claim 1, the PMRD subsystem comprising a lightweight dielectric case for providing protection from electrical shorting and enhance ease of integration.

7. The system of claim 1, the PMRD subsystem comprising:
maximum power point tracking circuitry for causing the flexible photovoltaic module to operate at its maximum power point;
charge control circuitry for controlling charging of an attached battery subsystem;
balance charge circuitry for ensuring balanced charging of the attached battery subsystem at least one regulated power circuits for operating electrical loads within the aerial vehicle;

8. The system of claim 7, the regulated power circuit subsystem combines an electronic filter to provide clean regulated power.

9. The system of claim 7, the regulated power circuit subsystem includes an means for monitoring the voltage and current of the output for data logging or streaming to a ground station.

10. The system of claim 1, the PMRD subsystem interfaces with a battery subsystem, the battery subsystem including a battery selected from the group consisting of a lithium ion (LiIon) battery, a lithium polymer (LiPo) battery, and a zinc-air battery.
